(19) United States
(12) Patent Application Publication
(10) Pub. No.: US 2025/0226806 A1
(43) Pub. Date: Jul. 10, 2025

(54) DIGITAL AMPLIFIERS TO MONITOR POWER

(71) Applicant: Hewlett-Packard Development Company, L.P., Spring, TX (US)

(72) Inventor: Kuo-Hsien Liu, Taipei City (TW)

(73) Assignee: Hewlett-Packard Development Company, L.P., Spring, TX (US)

(21) Appl. No.: 18/852,758

(22) PCT Filed: Apr. 7, 2022
(86) PCT No.: PCT/US2022/023832

§ 371 Date: Sep. 30, 2024

(51) Int. Cl. H03G 3/30; G01R 15/14; G01R 19/00

(52) U.S. Cl. CPC H03G 3/3089; G01R 15/146; G01R 19/0092; H03G 2201/103

(57) ABSTRACT

An example device includes a power circuit to receive power from a first power supply or a second power supply when the first power supply or the second power supply is respectively connected to the power circuit as a connected power supply. The first power supply and the second power supply provide different current. The example device further includes a current sensing circuit to sense a current provided by the connected power supply and a digital amplifier connected to the current sensing circuit to output a signal indicative of the current provided by the connected power supply. The digital amplifier applies a gain to the signal. The example device further includes a controller connected to the digital amplifier to monitor the signal. The controller is further to set the gain based on the connected power supply being the first power supply or the second power supply.

### BACKGROUND

Power circuits are used to deliver electrical power to a variety of everyday computing devices, such as notebook computers, desktop computers, tablet computers, All-in-One (AiO) computers, smartphones, servers, printers, scanners, and so on. A power circuit may connect a power source, such as a plug-in adaptor or battery, to a computing device and may monitor the power delivered.

### BRIEF DESCRIPTION OF THE FIGURES

FIG. 1 is a block diagram of an example device to monitor power of a connected power supply, the device including a digital amplifier with a gain that is settable based on the connected power supply.

FIG. 2 is a circuit diagram of an example device to monitor power of a connected power supply, the device including a digital amplifier with a gain that is settable based on the connected power supply.

FIG. 3 is a flowchart of an example method to monitor power of a connected power supply using a digital amplifier with a gain that is settable based on the connected power supply.

FIG. 4 is a flowchart of an example method to detect connected power supplies and monitor power delivered by a connected power supply using a digital amplifier with a gain set based on a priority of the connected power supply.

FIG. 5 is a block diagram of an example computing device to monitor power of a connected power supply using a digital amplifier with a gain that is settable based on the connected power supply.

### DETAILED DESCRIPTION

Many computing devices are capable of using power sources with different power delivery capacities. It is not uncommon for a computing device to be capable of operating from a range of power supplies that provide power at a desired voltage level with different wattages and currents. For example, a computing device may take power at 19.5 Volts (V) and may be operable with power supplies rated to deliver nominal power of 65, 90, or 120 Watts (W) with 3.33, 4.62, and 6.15 Amperes (A), respectively.

Monitoring the power delivered may include monitoring the current delivered at the desired voltage. A typical power monitoring circuit may include a current sense resistor and amplifier to convert a sensed current to a voltage signal and may further include a resistor divider or voltage divider to scale the voltage signal to a scale expected by a downstream circuit, such as a controller. If multiple power sources that deliver different levels of power are used, then often a specifically configured resistor divider is provided for each power source. Each resistor divider is configured to provide a signal at the scale expected by the downstream circuit. Activating a given resistor divider of the multiple resistor dividers may be done with switches that are controlled by the downstream circuit. This often means that the controller has a general-purpose input/output (GPIO) pin for each resistor divider that could be activated. This approach is complex, in that multiple resistor dividers and multiple GPIO pins are provided to support multiple power supplies. In addition, more resistor dividers mean more space required on a circuit board. A designer may compromise on the number of different power supplies supported to reduce circuit complexity and space used.

As described herein, a power monitoring circuit supports multiple power supplies with a digital amplifier, so as to reduce reliance on resistor dividers and corresponding controller pins. A gain of the digital amplifier may be controlled to map the power supplied by a connected power supply to a common scale. The gain may be set by a controller, such as an embedded controller (EC), based on the nominal power deliverable by the connected power supply. Accordingly, a more compact circuit with reduced complexity, by way of fewer resistor dividers and/or fewer controller pins used, may be realized.

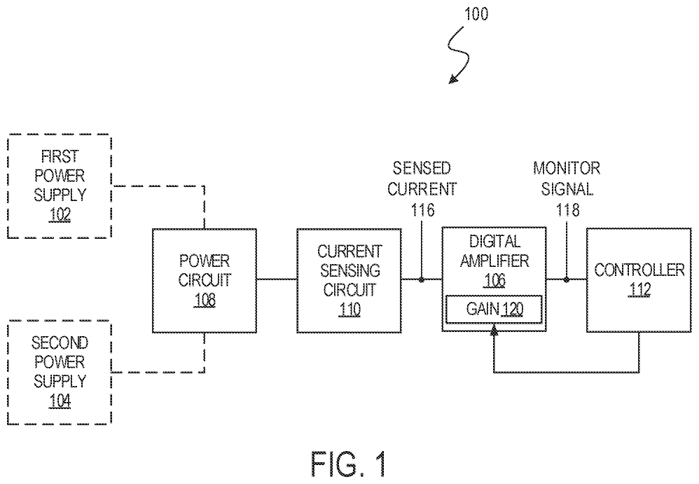

FIG. 1 shows an example device 100 to monitor power of a connected power supply 102, 104. The device 100 includes a digital amplifier 106 with a gain that is settable based on the connected power supply 102, 104. The device 100 may be provided to a computing device, such as a notebook computer, desktop computer, tablet computer, AiO computer, smartphone, server, printer, or scanner, to monitor power provided to components of the computing device.

The device 100 includes a power circuit 108, a current sensing circuit 110 connected to the power circuit 108, a digital amplifier 106 connected to the power circuit 108, and a controller 112 connected to the digital amplifier 106.

The power circuit 108 receives power from a connected power supply, such as a first power supply 102 or a second power supply 104, when respectively connected to the power circuit 108.

The power supplies 102, 104 provide different nominal or rated current (e.g., 3.33 A, 4.62 A, 6.15 A, etc.) and may provide the same nominal or rated voltage. The power supplies 102, 104 may be connected to the power circuit 108 via a switch or a physical connector plug/receptable. A power supply 102, 104 may be permanently physically connected to the power circuit 108 or may be removably connected to the power circuit 108. The power circuit 108 may include logic to switch between the power supplies 102, 104 to make an electrical connection to the selected power supply 102, 104. Any suitable number of power supplies 102, 104 may be selectively electrically connectable to the power circuit 108.

The current sensing circuit 110 senses a current 116 provided by the connected power supply 102, 104 via the power circuit 108.

The digital amplifier 106 may include a transconductance amplifier. The digital amplifier 106 takes the current 116 and outputs a monitor signal 118 indicative of the current 116. The digital amplifier 106 applies a gain 120 to the monitor signal 118. The gain 120 may be set to normalize the monitor signal 118 to a predetermined common scale, such as 2.0 V.

The controller 112 takes the monitor signal 118 provided by the digital amplifier 106 and may use the monitor signal 118 to monitor power actually provided by the connected power supply 102, 104. The controller 112 may provide the monitor signal 118 or a representation thereof to another component connected to the device 100. For example, when the device 100 is incorporated into a computing device, the controller 112 may provide the monitor signal 118 to a hardware or firmware component of the computing device, raise an alert if the monitor signal 118 indicates that the power supplied by the connected power supply 102, 104 deviates significantly from what is expected, or take other action.

The controller 112 sets the gain 120 of the digital amplifier 106 to provide the monitor signal 118 with a consistent scale irrespective of the nominal power expected to be provided by the connected power supply 102, 104. That is, controller 112 may set the gain 120 with regard to which of the power supplies 102, 104 is electrically connected to the power circuit 108 to provide power to the device 100. The controller 112 may determine the gain 120 to be inversely proportional to the rated or nominal current of the connected power supply 102, 104. For example, if the first power supply 102 provides a higher current than the second power supply 104, then the controller 112 sets the gain 120 lower when the first power supply 102 is connected as compared to when the second power supply 104 is connected.

The controller 112 may implement a function to compute the gain 120 or may look up the gain 120 from a lookup table that correlates gains to rated currents of different power supplies 102, 104.

The controller 112 may detect electrical connection of the power supply 102, 104 and set the gain 120 dynamically in response to such detection. The controller 112 may be connected to the power circuit 108, the current sensing circuit 110, or another component to receive a signal indicative of the rated or nominal current or power of the connected power supply 102, 104. For example, the controller 112 may be connected to ID pins of the power supplies 102, 104, where a power supply 102, 104 applies a voltage to its ID pin to indicate its rated power and/or current. In another example, the power supply 102, 104 may provide its nominal current or power via a communication protocol, such as a Universal Serial Bus™ (USB) Power Delivery protocol. In other examples, different portions of the power circuit 108 may be connected to different ports, receptables, or internal connection, so that the portion of the power circuit 108 that receives power is indicative of the connected power supply. Connector shape and size may limit certain power supplies to be connected to certain ports/receptables, so that connector may be indicative of rated power. For example, one of several lines may be pulled high when a respective power supply is connected. The controller 112 may be connected to such lines and detect connection of a power supply with a particular rated power based on the line that is pulled high.

Accordingly, the device 100 generates a monitor signal 118 that conforms to a predetermined common scale, so that regardless of the specific different power supply 102, 104 connected, an actual delivered power can be monitored with regard to the common scale and without added complexity, such as a range of resistor dividers.

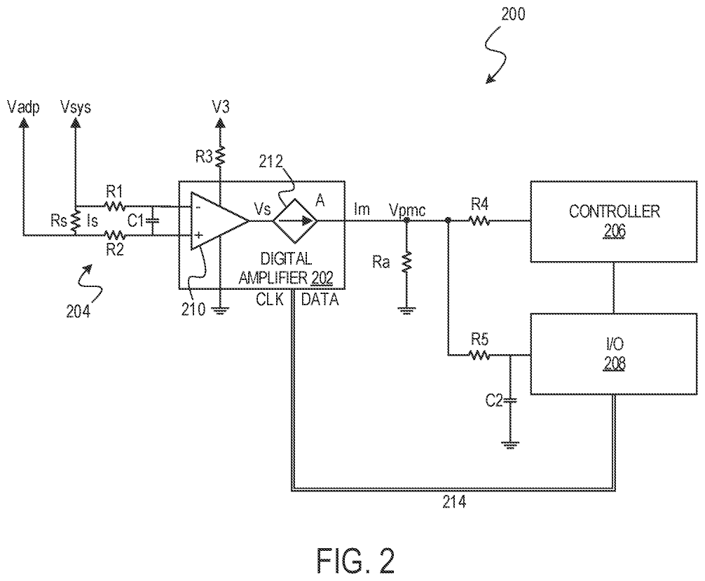

FIG. 2 shows an example device 200 to monitor power of a connected power supply. The device 200 includes a digital amplifier 202 with a gain A that is settable based on the connected power supply. The device 200 may be provided to a computing device, such as a notebook computer, desktop computer, tablet computer, AiO computer, smartphone, server, printer, or scanner, to monitor power provided to components of the computing device. Features and aspects of the device 100 may be used with the device 200, with like reference numerals or like terminology denoting like components.

The device 200 includes a current sense circuit 204, a digital amplifier 202 connected to current sense circuit 204, a controller 206 connected to the digital amplifier 202, and an input/output (I/O) circuit 208 connected to the controller 206 and the digital amplifier 202.

The current sense circuit 204 includes a shunt resistor (current sense resistor) Rs connected between a supply voltage Vadp and a system voltage Vsys. The shunt resistor Rs develops a voltage indicative of a source current Is provided by the connected power supply.

The supply voltage Vadp is provided by the connected power supply, which may be one of several connectable power supplies capable of providing the same nominal supply voltage Vadp at different nominal currents and therefore different rated powers.

The current sense circuit 204 further includes resistors R2, R3 at each end of the shunt resistor Rs to provide potential proportional to the source current Is. The resistors R1, R2 may be connected by a capacitor C1.

The digital amplifier 202 includes a current sense amplifier 210 and a transconductance amplifier 212 connected to the current sense amplifier 210.

The current sense amplifier 210 senses the source current Is provided by the connected power supply as a voltage across the shunt resistor Rs and provides a respective voltage Vs to the transconductance amplifier 212. The current sense amplifier 210 may include an operational amplifier that takes input as the voltage across the shunt resistor Rs via respective resistors R2, R3. The current sense amplifier 210 may be driven by a voltage V3, which may nominally be the system voltage Vsys, via a resistor R3.

The transconductance amplifier 212 applies a gain A to the voltage Vs provided by the current sense amplifier 210 and outputs a corresponding monitor current Im, which is indicative of the current suppled to the system by the connected power supply.

The controller 206 may include a processor, microprocessor, microcontroller, or similar device capable of executing instructions, such as instructions stored on a non-transitory machine-readable medium, such as electrically erasable programmable read-only memory (EEPROM), read-only memory (ROM), flash memory, or similar non-volatile memory. A machine-readable medium may be integrated with the controller 206 on the same integrated circuit (chip) or may be a separate integrated circuit. The controller 206 may be termed an embedded controller or EC. Functionality attributed to the controller 206 may be implemented by executable instructions.

The controller 206 references a monitor voltage Vpmc corresponding to the monitor current Im to monitor power provided by the power supply, that is, power provided at the supply voltage Vadp to enable operation of the computing device at the system voltage Vsys. The controller 206 may provide an indication of monitored power to a hardware or firmware component of the computing device to which the device 200 belongs. The controller 206 further selectively sets the gain A of the transconductance amplifier 212 based on the connected power supply to normalize the monitor voltage Vpmc to a predetermined scale.

The device 200 may further include a scale resistor Ra connected between the digital amplifier 202 and the controller 206 and connecting the monitor current Im to ground. The scale resistor Ra may be selected to provide a useful predetermined scale, such as 2 V, for the monitor voltage Vpmc that corresponds to the monitor current Im. An analog-to-digital converter (ADC) of the controller 206 may thus consume a monitor voltage Vpmc that ranges from about 0 V to about 2 V. If the ADC has a full range of 3.3 V, then 0-2 V provides a suitably precise measurement range with room for detecting power surges.

The gain A may be a function of the selected range of the monitor voltage Vpmc, a resistance of the scale resistor Ra, and a rated current or rated power of the connected power supply. For example, a computable function may be as follows:

$$A = ( Vpmc Range / Ra ) / Power Supply Rated Current$$

where:
A is the gain to be determined,
Vpmc Range is a predetermined range,
Ra is a scale resistance, and

Power Supply Rated Current is obtainable from the connected power supply.

The controller 206 may be programmed with such a function to compute the gain A. The scale resistor Ra and the range for the monitor voltage Vpmc may be considered constant. As such, during operation, the controller 206 may compute the gain A directly from the power supply's rated power or current.

Table 1 provides examples of different gains for different wattages of power supply.

TABLE 1
Example Gains

| | | | | Current |
|---|---|---|---|---|
| Power Supply | Power Supply | | Vpmc | Source |
| Rated Power | Rated Current at | Ra | Range | Gain |
| (Watts) | 19.5 V (Amps) | (ohms) | (Volts) | (μA/A) |
| 65 | 3.33 | 100k | 2 | 6.00 |
| 90 | 4.62 | 100k | 2 | 4.33 |
| 120 | 6.15 | 100k | 2 | 3.25 |

The controller 206 may be programed with a lookup table that correlates gain A to power supply rated wattage or current. In operation, the controller 206 may look up the gain A for the power supply determined to be connected.

The I/O circuit 208 may be considered part of the controller 206 or may be considered a separate and distinct circuit. In various examples, the controller 206 and the I/O circuit 208 include separate integrated circuits. In other examples, the controller 206 and the I/O circuit 208 are provided on the same integrated circuit. The I/O circuit 208 may communicate with the digital amplifier 202 using a suitable connection, such as an Inter-Integrated Circuit (I2C) bus. The I/O circuit 208 may be a Super I/O (SIO) circuit.

The I/O circuit 208 may receive a command from the controller 206 and, in response, provide a gain control signal 214 to the digital amplifier 202 to set the gain A of the transconductance amplifier 212.

In various examples consistent with FIG. 2, the following values may be selected for the voltages and discrete components provided: Vadp (nominal)=19.5 V, Vsys (nominal)=19.5 V, Rs=5 mΩ, R1=1Ω, R2=1Ω, C1=0.1 μF, V3 (nominal)=19.5 V, R3=2.2Ω, Ra=100 kΩ, R4=0Ω, R5=0Ω, and C2=1000 pF.

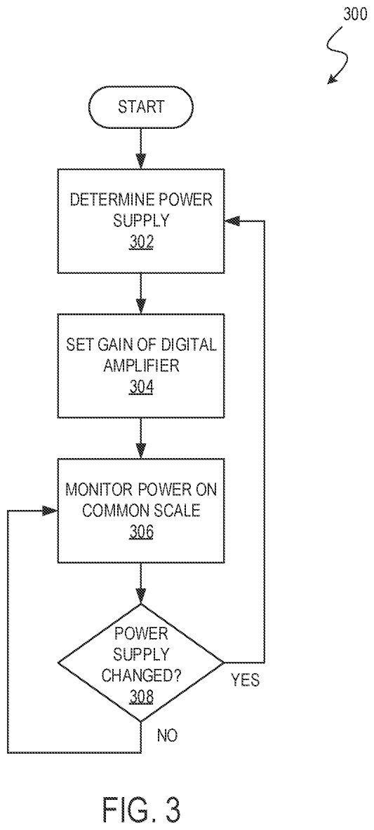

FIG. 3 shows an example method 300 of monitoring power of a connected power supply using a digital amplifier with a gain that is settable based on the connected power supply. The method 300 may be implemented by executable instructions. The devices 100, 200 may be referenced for descriptions of components usable with the method 300.

At block 302, a power supply is electrically connected to a load, such as a computing device. A rated current or rated power of the power supply is determined. This may be done by referencing an ID pin of the power supply. In other examples, this may be done by communication between the power supply and the load, such as by a protocol that negotiates power delivery parameters (e.g., USB Power Delivery). In still other examples, different power supplies are distinguished by connection, such as receptable/port or internal connection, e.g., battery connection. That is, when a certain port or circuit receives power, it may be taken to mean that a power supply with a certain rated power is connected. In still other examples, a circuit may be configured to measure a current, voltage, or other property initially provided by the power supply with the assumption that the property is reflective of the rated power of the power supply.

At block 304, the rated power or rated current is used to determine the gain of the digital amplifier. A computed function or look up table may be used to look up gain based on rated power or rated current. The gain is different for different rated powers or currents to establish a common scale for a set of different connectable power supplies. The gain is then set at the digital amplifier.

At block 306, the power delivered is monitored on the common scale, while the power supply is unchanged, via block 308.

At block 308, if the power supply is changed, the method 300 returns to block 302 to determine the connected power supply. Accordingly, the gain of the digital amplifier is set in response to connection of a power supply. The method 300 may be performed continuously until the computing device or other load is turned off or removed.

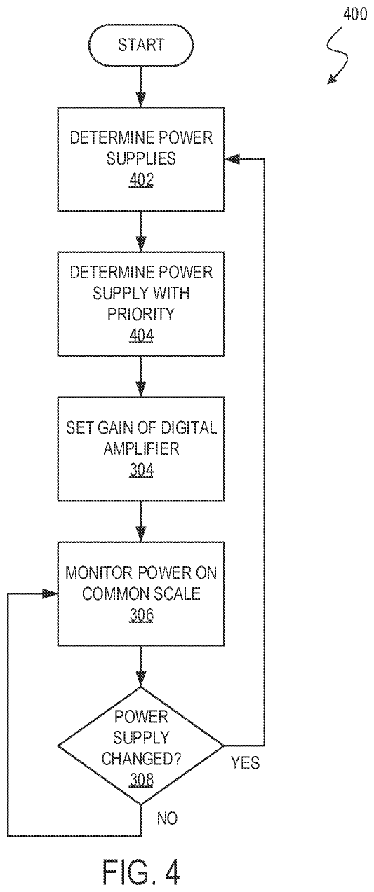

FIG. 4 shows an example method 400 of detecting connected power supplies and monitoring power delivered by a connected power supply using a digital amplifier with a gain set based on a priority of the connected power supply. The method 400 may be implemented by executable instructions. The devices 100, 200 may be referenced for descriptions of components usable with the method 400. The method 300 may be referenced for description not repeated here for sake of brevity.

At block 402, several different power supplies are electrically connected to a load, such as a computing device. For example, a battery and a plug-in adaptor may both be connected and active at a computing device. In another example, a tablet computer may be plugged into a wall outlet and to a power/communications port (e.g., a USB port) of a desktop computer. A rated current or rated power of each power supply is determined, with reference to block 302 above.

At block 404, a relative priority of each power supply is determined, so that one of the multiple connected power supplies may be monitored. Priority may be predetermined. For example, a tablet computer may have its battery prioritized over a USB connection, which in turn may be prioritized over a wall connection. In another example, priority may be based on rated power, with higher rated powers having higher priority. In still another example, priority may be given to the power supply currently powering the device. That is, the device may control which of multiple power supplies power is to be taken from and, for power monitoring purposes, priority may be determined in the same way.

At block 304, the rated power or rated current of the highest priority power supply used to determine the gain of the digital amplifier. The gain is set at the digital amplifier.

At block 306, the power delivered is monitored on the common scale, while the power supply is unchanged, via block 308.

At block 308, if the power supply is changed, the method 400 returns to block 402 to determine the connected power supplies. Accordingly, the gain of the digital amplifier is set in response to connection of power supplies with regard to priority among power supplies. The method 400 may be performed continuously until the computing device or other load is turned off or removed.

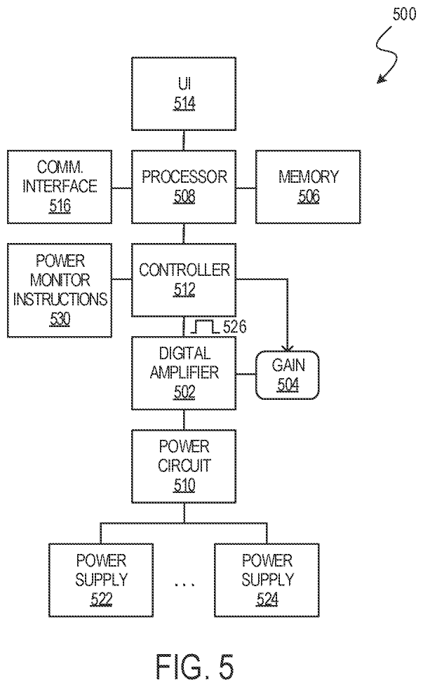

FIG. 5 shows an example computing device 500 to monitor power of a connected power supply using a digital amplifier 502 with a gain 504 that is settable based on the connected power supply. The computing device 500 may be a notebook computer, desktop computer, tablet computer, AiO computer, smartphone, server, printer, scanner, or similar computing device.

The computing device 500 includes memory 506, a processor 508, a power circuit 510, a digital amplifier 502, and a controller 512. The computing device 500 may further include a user interface 514 and a communications interface 516. The computing device 500 may receive power from any suitable number of power supplies 522, 524, whether internal or external, having any suitable rated power.

The memory 506 and processor 508 are connected and operable to realize the intended functionality of the device 500. The memory 506 may include a non-transitory machine-readable medium, whether volatile, non-volatile, or a combination of such. The processor 508 may include a central processing unit (CPU) or microprocessor. The processor 508 may execute an operating system and applications.

The user interface 514 may support the intended functionality of the device 500 and may include a display device, touchscreen, button, keypad, mouse, speaker, microphone, etc.

The communications interface 516 may support the intended functionality of the device 500 and may include a network adaptor and driver to facilitate data communications over a computer network.

The power circuit 510 is electrically connectable to multiple power supplies 522, 524 to power the memory 506, processor 508, and other power-consuming components of the computing device 500.

The digital amplifier 502 is connected to the power circuit 510. The digital amplifier 502 senses a source current provided by the currently connected power supply 522, 524 or, in the case of multiple connected power supplies, a priority power supply 522, 524. The digital amplifier 502 generates a monitor signal 526 based on the source current and a gain 504.

The digital amplifier 502 may include a current sense amplifier and a transconductance amplifier connected to the current sense amplifier. The current sense amplifier senses a source current provided by provided by the currently connected or priority power supply 522, 524 and outputs a respective voltage to the transconductance amplifier. The transconductance amplifier applies the gain 504 to the respective voltage received from the current sense amplifier to obtain the monitor signal 526.

The controller 512 is connected to the digital amplifier 502 and may be connected to the processor 508. The controller 512 references the monitor signal 526 provided by the digital amplifier 502 to monitor the power provided by the connected or priority power supply 522, 524. The controller 512 may provide power monitoring to the processor 508, so that the processor 508 can control the computing device 500 accordingly.

The controller 512 further selectively sets the gain 504 of the digital amplifier 502 based on a nominal output (i.e., rated power or current) of the connected or priority power supply 522, 524. The gain 504 is selected to normalize the monitor signal 526 to a common scale, so that the controller 512 and/or processor 508 can reference the monitor signal 526 irrespective of the specific connected or priority power supply 522, 524.

The controller 512 may determine the nominal output of the connected or priority power supply 522, 524, determine the gain 504, and set the gain 504 of the digital amplifier 502 in response to a power supply 522, 524 being connected to the power circuit 510. The controller 512 may determine the gain 504 to be inversely proportional to a nominal current or a nominal power of the connected or priority power supply 522, 524.

Power monitor instructions 530 may be provided in non-volatile memory in or accessible to the controller 512. The instructions 530 as executed by the controller 512 may determine the nominal current or nominal power of the connected or priority power supply 522, 524 and determined the respective gain 504, accordingly. The instructions 530 may implement a lookup table or computed function to provide this functionality.

In view of the above, it should be apparent that a digital amplifier with controlled gain may be used to monitor power delivered to a device to reduce complexity and space used by power monitoring circuitry. In addition, various different power supplies can be supported with the same circuit and supported power supplies can be updated by updating a function or lookup table with little to no change to hardware.

It should be recognized that features and aspects of the various examples provided above can be combined into further examples that also fall within the scope of the present disclosure. In addition, the figures are not to scale and may have size and shape exaggerated for illustrative purposes.

1. A device comprising:
a power circuit to receive power from a first power supply or a second power supply when the first power supply or the second power supply is respectively connected to the power circuit as a connected power supply, wherein the first power supply and the second power supply provide different current;
a current sensing circuit to sense a current provided by the connected power supply;
a digital amplifier connected to the current sensing circuit to output a signal indicative of the current provided by the connected power supply, wherein the digital amplifier applies a gain to the signal; and
a controller connected to the digital amplifier to monitor the signal;
wherein the controller is further to set the gain based on the connected power supply being the first power supply or the second power supply.

2. The device of claim 1, wherein the controller is to detect the connected power supply and set the gain in response to detection of the connected power supply.

3. The device of claim 2, wherein the controller is to set the gain according to a priority of the first power supply and the second power supply when both the first power supply and second power supply are detected as connected to the power circuit.

4. The device of claim 1, wherein the controller is to determine the gain as inversely proportional to a rated power or a rated current of the connected power supply.

5. The device of claim 1, further comprising a scale resistor connected between the digital amplifier and the controller.

6. The device of claim 1, wherein the gain is a function of a voltage range of the signal, a resistance of the scale resistor, and a rated power or a rated current of the connected power supply.

7. A device comprising:
a digital amplifier including a current sense amplifier and a transconductance amplifier connected to the current sense amplifier, wherein the current sense amplifier is to sense a source current provided by a power supply connected to the device and provide a respective voltage to the transconductance amplifier, wherein the transconductance amplifier is to apply a gain to the respective voltage and output a corresponding monitor signal; and
a controller connected to the digital amplifier to reference the monitor signal to monitor power provided by the power supply;
wherein the controller is further to selectively set the gain of the transconductance amplifier based on the power supply to normalize the monitor signal to a predetermined scale.

8. The device of claim 7, wherein the controller is to detect connection of the power supply and set the gain in response to the detection.

9. The device of claim 7, wherein the controller is to compute the gain as inversely proportional to a rated power or a rated current of the power supply.

10. The device of claim 7, wherein the controller is to look up the gain based on a rated power or a rated current of the power supply.

11. The device of claim 7, further comprising a scale resistor connected between the digital amplifier and the controller, wherein the scale resistor is selected to provide the predetermined scale.

12. A computing device comprising:
memory;
a processor;
a power circuit to receive connection of a power supply to power the memory and the processor;
a digital amplifier to sense a source current provided by the power supply and generate a monitor signal based on the source current and a gain; and
a controller connected to the digital amplifier to reference the monitor signal to monitor the power provided by the power supply, the controller further to selectively set the gain of the digital amplifier based on a nominal output of the power supply to normalize the monitor signal to a common scale.

13. The computing device of claim 12, wherein the digital amplifier includes a current sense amplifier and a transconductance amplifier connected to the current sense amplifier, wherein the current sense amplifier is to sense the source current provided by the power supply and output a respective voltage to the transconductance amplifier, wherein the transconductance amplifier is to apply the gain to the respective voltage to obtain the monitor signal.

14. The computing device of claim 12, wherein the controller is to determine the nominal output of the power supply, determine the gain, and set the gain of the digital amplifier in response to the power supply being connected to the power circuit.

15. The computing device of claim 12, wherein the controller is to determine the gain as inversely proportional to a nominal current or a nominal power of the power supply.
